(19) United States
(12) Patent Application Publication
(10) Pub. No.: US 2003/0052411 A1
(43) Pub. Date: Mar. 20, 2003

(54) Semiconductor device and method for manufacturing the same

(76) Inventor: Katsumi Mori, Sakata-shi (JP)

Correspondence Address: HARNESS, DICKEY & PIERCE, P.L.C., P.O. BOX 828, BLOOMFIELD HILLS, MI, 48303, US

(21) Appl. No.: 10/226,654

(22) Filed: Aug. 23, 2002

(30) Foreign Application Priority Data
Aug. 23, 2001 (JP) 2001-252729

(51) Int. Cl. H01L 23/48; H01L 29/40; H01L 21/48

(52) U.S. Cl. 257/758; 438/118; 438/622; 257/760; 257/773; 257/776

(57) ABSTRACT

A semiconductor device 100 includes wiring layers 12 disposed in a specified pattern on a base 10, and an interlayer dielectric layer 20 that covers the wiring layers 12. The interlayer dielectric layer 20 includes a stress relieving dielectric layer 22 disposed in a specified pattern on the base 10, and a planarization dielectric layer 26 that covers the wiring layers 12 and the stress relieving dielectric layers 22, and is formed from a liquid dielectric member. The interlayer dielectric layer 20 may further include a base dielectric layer 24 and a cap dielectric layer 28.

### BACKGROUND OF THE INVENTION

1. Technical Field of the Invention

The present invention relates to semiconductor devices and methods for manufacturing the same, and more particularly to a semiconductor device having an interlayer dielectric layer in which the dielectric layer is well embedded in spaces between wiring layers even when the spaces between the wiring layers are particularly narrow, and a method for manufacturing the same.

2. Background Technology and Problems to be Solved by the Invention

In semiconductor devices such as LSIs, the width of wiring layers has become small and the gap between the wiring layers has also become narrow due to further device miniaturization, higher densification, and greater number of multiple layers. For example, in the 0.13 μm generation design rule, the minimum line width of a metal wiring layer is 0.2 μm, and the minimum gap is 0.22 μm. When silicon oxide is embedded by a CVD method in such a narrow gap between the wiring layers, voids may be generated in the embedded silicon oxide layer because the gap between the wiring layers is too narrow, resulting in an embedding failure.

Coated silicon oxide called SOG (Spin On Glass) is provided by spin-coating a wafer with a dielectric film material dissolved in an organic solvent, and then hardening the layer by a heat treatment. Such a SOG is excellent in its embedding ability due to its high fluidity. However, when the SOG is subject to a heat treatment for thermosetting, which is called “curing”, the SOG layer shrinks as the organic solvent evaporates.

The inventors of the present invention have confirmed that, when a SOG layer is used as an interlayer dielectric layer between wiring layers that are formed according to, for example, the 0.13 μm generation design rule, a shrinkage occurs in the SOG layer, which causes a compression force against the wiring layers in their thickness direction, which would likely deform metal wiring layers such as aluminum layers in particular. When wiring layers are deformed, the wiring reliability and migration resistivity may lower. In addition, deformations in wiring layers would occur particularly in wiring layers having patterns that are isolated from others.

It is an object of the present invention to provide a semiconductor device having an interlayer dielectric layer with an excellent embedding property for gaps between adjacent wiring layers even when they are formed in accordance with, for example, a sub 0.13 μm generation design rule, and a method for manufacturing the same.

### SUMMARY OF THE INVENTION

A semiconductor device in accordance with the present invention comprises:

a wiring layer disposed in a specified pattern on a base;

a stress relieving layer disposed in a specified pattern on the base and formed from the same material as that of the wiring layer; and

an interlayer dielectric layer including at least a planarization dielectric layer that covers the wiring layer and the stress relieving layer and is formed from a liquid dielectric material.

The semiconductor device in accordance with the present invention comprises a stress relieving layer having a specified pattern between wiring layers. As a result, even when a planarization dielectric layer that is embedded in spaces between the wiring layers causes a compression force that works on the wiring layers, the compression force is absorbed by the stress relieving layer. As a result, the compression force that works on the wiring layers can be diminished and deformations of the wiring layers by the compression force can be prevented. The stress relieving layer may be disposed in such a manner mainly to relieve compression forces that may be applied to the wiring layers due to the planarization dielectric layer. The present invention is preferably applied to layers in which a metal wiring layer that is apt to deform by a compression force is formed.

The planarization dielectric layer may be a silicon oxide layer or another dielectric layer having a low dielectric constant formed by a coating method. Here, the “dielectric layer having a low dielectric constant” is a layer typically having a relative dielectric constant of 3.0 or lower.

The stress relieving layer may preferably have a higher density and greater mechanical strength than those of the planarization dielectric layer composed of a silicon oxide layer formed by, for example, a CVD method.

Also, the stress relieving layer may be disposed at least in a rough or sparse pattern region. Wiring layers in a rough pattern region would more likely be affected by a compression force caused by a planarization dielectric layer compared to those in a dense pattern region, and therefore the necessity to provide a stress relieving layer in the rough pattern region is high. Here, the “dense pattern region” means a region with a high wiring density in which wiring layers are disposed, for example, at the minimum gaps according to an applied design rule. Also, the “rough pattern region” means, for example, a region in which wiring layers are present isolated from other wiring layers or a region with a lower wiring density than that of the dense pattern region. Also, the “design rule” in accordance with the present invention means a variety of design rules stipulated in the ITRS (International Technology Roadmap for Semiconductor) 2000.

The stress relieving layer may have, in accordance with the applied design rule, a minimum line width and a minimum gap for wiring layers on which the stress relieving layer is formed. Also, the stress relieving layer may have a pattern that is different from a so-called dummy pattern that is provided to prevent generation of dishing in a chemical mechanical polishing (CMP) process.

The interlayer dielectric layer may further comprise a base dielectric layer formed on the wiring layer and the stress relieving layer, and a cap dielectric layer formed on the planarization dielectric layer.

A method for manufacturing a semiconductor device in accordance with the present invention comprises the steps of:

forming the wiring layer and a stress relieving layer having a specified pattern on the base; and

forming a planarization dielectric layer with a liquid dielectric material to cover the wiring layer and the stress relieving layer.

In this manufacturing method, the wiring layer and the stress relieving layer are formed in the same step.

The step of forming a planarization dielectric layer may be performed by a coating method, or a liquid CVD method.

The manufacturing method in accordance with the present invention may further include the steps of forming a base dielectric layer on the wiring layer and the stress relieving layer, and forming a cap dielectric layer on the planarization dielectric layer.

### BRIEF DESCRIPTION OF THE DRAWINGS

FIG. 1 schematically shows in cross section a step of a method for manufacturing a semiconductor device in accordance with an embodiment of the present invention.

FIG. 2 schematically shows in cross section a step of the method for manufacturing a semiconductor device in accordance with the present invention.

FIG. 3 schematically shows in cross section a step of the method for manufacturing a semiconductor device in accordance with the present invention.

FIG. 4 schematically shows in cross section a step of the method for manufacturing a semiconductor device in accordance with the present invention.

FIG. 5 schematically shows a cross-sectional view of a semiconductor device in accordance with the present invention.

### DETAILED DESCRIPTION OF THE PREFERRED EMBODIMENTS OF THE PRESENT INVENTION

One exemplary embodiment of the present invention will be described below with reference to the accompanying drawings.

Device

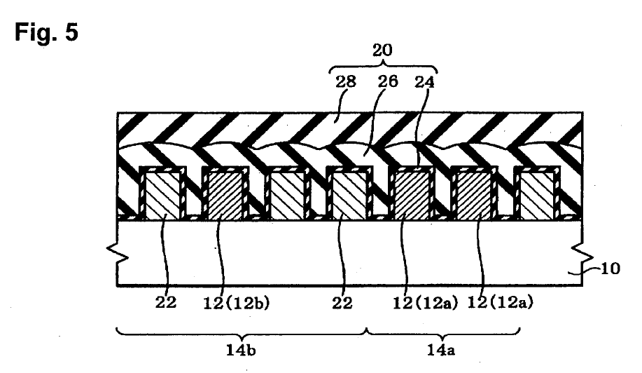

First, a semiconductor device in accordance with the present embodiment will be described. FIG. 5 schematically shows a crosssectional view of a main part of a semiconductor device of the present embodiment, and FIG. 2 schematically shows a plan view of a part of layers of the semiconductor device.

The semiconductor device includes a base 10, wiring layers 12 (12a, 12b) formed on the base 10, and an interlayer dielectric layer 20 that is formed in a manner to cover the wiring layers 12. Here, the “base” indicates a structural body below one interlayer dielectric layer 20. For example, when the interlayer dielectric layer 20 is an interlayer dielectric layer in the second layer, the base 10 may be formed, although not shown, from a semiconductor substrate, and an element isolation region, a semiconductor element such as a MOSFET and wiring layers formed on the semiconductor substrate, and an interlayer dielectric layer in the first layer. The interlayer dielectric layer 20 in which the present invention is applied may be an interlayer dielectric layer at any location; but in particular, it may preferably be an interlayer dielectric layer for covering a metal wiring layer.

The example in FIG. 5 and FIG. 2 shows wiring layers 12a in a dense pattern region 14a and a wiring layer 12b in a rough or sparse pattern region 14b. The wiring layers 12a and 12b may be formed from metal material mainly selected, for example, from aluminum, aluminum alloy, copper or copper alloy.

The stress relieving layers 22 having a specified pattern are disposed on the base 10 between the wiring layers 12. The pattern of the stress relieving layers 22 is not limited to a particular pattern, and may be, for example, continuous as indicated in FIG. 2, or may be composed of blocks of layers disposed in a discontinuous manner. Preferably, the stress relieving layer 22 may continuously extend at least in a direction in which the wiring layers 12 extend (in a length direction) as indicated in FIG. 2, in view of the function of relieving stresses. By disposing the stress relieving layer 22 in such a manner, stresses can be uniformly absorbed.

The stress relieving layers 22 are formed at least in the rough pattern region 14b. In other words, the stress relieving layers 22 may be disposed such that, when disposed between the wirings 12, the influence of compression forces of the planarization dielectric layer 26 that work on the wiring layers 12 can be suppressed, and deformations of the wiring layers 12 can be prevented. Also, the stress relieving layers 22 may be formed with the minimum gap and minimum line width for wiring layers according to the applied design rule. For example, according to the 0.13 μm generation design rule, the minimum line width of metal wiring layers is 0.20 μm, and the minimum gap is 0.22 μm. By forming the stress relieving layers 22 according to such a rule, the stress relieving layers with miniature patterns can be formed, which can suppress the influence of compression forces of the planarization dielectric layer 26 that may act on the wiring layers 12 to a minimum level.

Stress relieving layers in accordance with the present invention differ in the following aspects from so-called dummy patterns that are formed to improve planarization in a CPM process. Since dummy patterns are formed to improve the degree of flatness of the entire surface of a substrate, or to improve the uniformity in polishing the entire surface in a CMP process, such dummy patterns are disposed regularly across the entire surface of a wafer. In contrast, stress relieving layers in accordance with the present invention can be provided in any specific areas to achieve the stress relieving function described above, and may not be disposed regularly across the entire surface of a wafer.

Also, depending on the requirements, dummy patterns 30 for a CMP process, which have a pattern different from the pattern of the stress relieving layers 22, may be provided as shown in FIG. 2. The dummy patterns 30 may be formed from the same material as that of the wiring layers 12 and the stress relieving layers 22. In this case, the dummy patterns 30 can be formed by the same process that form the signal lines 12 and the stress relieving layers 22. In the example shown in the figure, the dummy patterns 30 have a greater width than that of the stress relieving layers 22. For example, they are rectangular patterns having a size of 2.0 μm, and regularly disposed.

The interlayer dielectric layer 20 that covers the wiring layers 12 and the stress relieving layers 22 includes a base dielectric layer 24, a planarization dielectric layer 26 and a cap dielectric layer 28.

The base dielectric layer 24 is a layer that is formed to avoid direct contact between the wiring layers 12 and the planarization dielectric layer 26. The planarization dielectric layer 26 to be described later in detail generally has a porous structure and high moisture absorbability. Therefore, when the planarization dielectric layer 26 directly contacts the wiring layers, the wiring layers may be corroded, or cracks may be generated in the interlayer dielectric layer as the layer itself is weak. To avoid such problems, normally, the base dielectric layer 24 can be formed by a silicon oxide layer that is dense and has a great mechanical strength. Such a silicon oxide layer may be formed from a silicon oxide layer that can be obtained by a CVD method, such as, for example, a SiH₄—O₂ group normal pressure CVD, SiH₄—N₂O group CVD, TEOS—O₂ group plasma CVD, SiH₄—O₂ group high-density plasma CVD or the like.

The kinds of gases that are used for each of the CVD methods are not limited to those mentioned above, but can be any of various kinds of gases. Also, the base dielectric layer 24 has a thickness that can provide the functions described above, for example, 10-50 nm.

The planarization dielectric layer 26 is formed from a liquid dielectric member having an excellent step covering property. Such a liquid dielectric member may be generally grouped into SOG that is obtained by a coating method and silicon oxide that is obtained by a liquid CVD. The material of the planarization dielectric layer 26 may be either SOG or silicon oxide that is formed by a liquid CVD method, and may preferably be SOG because it can be formed with a relatively simple facility and therefore is highly economical.

Silicon oxide formed by the SOG or liquid CVD method may not be particularly limited, and may be any one of those ordinarily used.

The SOG may be formed by spin-coating dielectric material that is dissolved in an organic solvent on a wafer, and then conducting a heat treatment after the coating step. A typical heat treatment is composed of heat treatment for removing the solvent, which is called “baking”, and heat treatment for thermosetting, which is called “curing”. The SOG is generally grouped into organic SOG and inorganic SOG. The inorganic SOG includes silicate groups, alkoxy silicate groups, and polysilazane groups.

In the liquid CVD, a liquid reaction intermediate is deposited on the base, and then the reaction intermediate is changed to a complete oxide film by a heat treatment or the like. The methods listed below are known as the type of liquid CVD method described above:

(a) Thermal CVD with TEOS and 03 (Temperature: about 400° C.)

(b) Plasma reaction with Si (CH₃)₄ and O₂ (Substrate temperature: from −20° C. to −40° C.)

(c) Plasma reaction with TEOS and H₂O (Substrate temperature: from 60° C. to 120° C.)

(d) Plasma reaction with SiH₄ and O₂ (Substrate temperature: −80° C. or lower)

(e) Heat treatment reaction with SiH₄ and H₂O₂ (Substrate temperature: about 0° C.) under reduced pressure

As to the planarization dielectric layer 26 that is formed from a liquid dielectric material, the layer is formed on the base in a liquid state in the SOG process, and in a state of liquid reaction intermediate in the liquid CVD, and thus the layer has an excellent step covering property. As a result, a dielectric layer having a good embedding property can be formed without generating voids even in gaps between the wiring layers 12a and 12a in the dense pattern region 14a where the layers are disposed with the minimum gap according to, for example, a sub 0.13 μm generation design rule. Also, a dielectric layer having an excellent embedding property can be formed not only in the gaps between the wiring layers 12, but also gaps between the wiring layers 12 and the stress relieving layers 22, and gaps between the adjacent stress relieving layers 22.

The cap dielectric layer 28 is formed in contact with the planarization dielectric layer 26 for the same reasons described above in conjunction with the base dielectric layer 24. When the interlayer dielectric layer 20 is planarized by a CMP process, the cap dielectric layer 28 is formed with a film thickness that takes into account a thickness to be polished by the CMP. Also, the same film growth method and material for the base dielectric layer 24 may be used for the cap dielectric layer 28.

With the semiconductor device in accordance with the present invention, the following effects are achieved.

The semiconductor device in accordance with the present invention includes the stress relieving layer 22 having a specified pattern between the wiring layers 12, in particular, in the rough pattern region 14b. For this reason, even when compression forces caused by the planarization dielectric layer 26 that is embedded between the wiring layers 12 work on the wiring layers 12, the compression forces are absorbed by the stress relieving layer 22. As a result, the compression forces that may work on the wiring layers 12 can be diminished relatively, and deformations of the wiring layers 12 by the compression forces can be prevented. For example, when wiring layers are formed according to a sub 0.13 μm generation design rule, and a minimum gap between the wirings is 0.18-0.22 μm, a compression force caused by the planarization dielectric layer 26 would not deform or crush the wiring layers.

With the semiconductor device in accordance with the present invention, even when a planarization dielectric layer 26 is used which has difficulty obtaining a large mechanical strength, the stress relieving layers 22 that are present with a certain density among the planarization dielectric layer 26 absorb its shrinking force (i.e., a compression force against the wiring layers 12 and the stress relieving layers 22), such that cracks are not generated in the planarization dielectric layer 26.

Also, the stress relieving layers 22 can function as dummy patterns that prevent a polishing defect which is called dishing in a CMP process.

Manufacturing Method

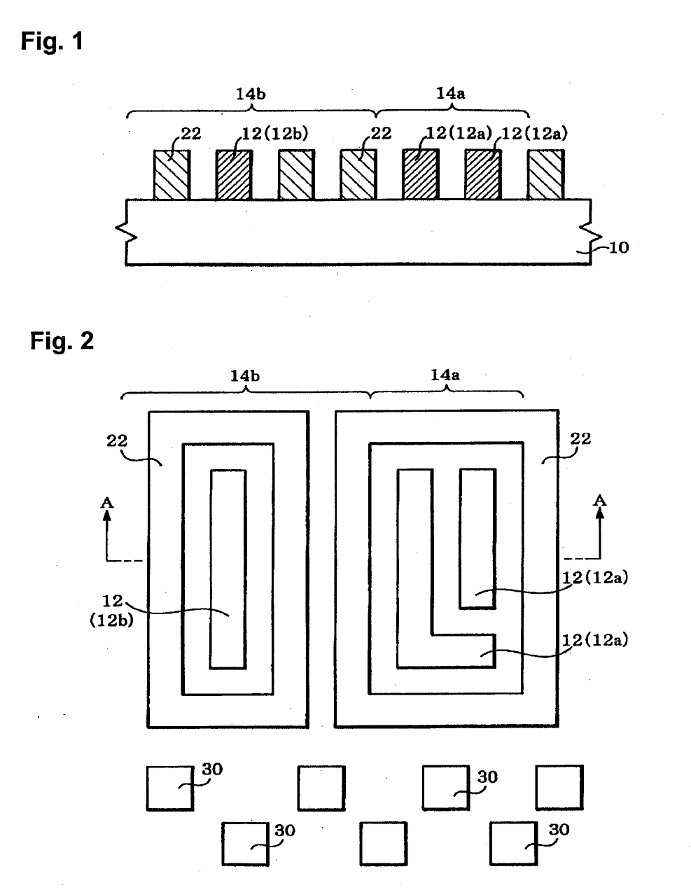

Next, one example of a method for manufacturing the semiconductor device shown in FIG. 5 will be described. FIGS. 1-4 schematically show in cross section steps of the manufacturing method, which show portions taken along line A-A in FIG. 2.

As shown in FIGS. 1 and 2, a conductive layer composed of metal or the like is formed on a base 10, and then the conductive layer is patterned by generally practiced lithography and etching to form wiring layers 12 and stress relieving layers 22. Also, in this step, as shown in FIG. 2, dummy patterns 30 may be formed depending on the requirements to prevent dishing in a CMP process. In the example shown in FIG. 1, the wiring layers 12 in a dense pattern region 14a are indicated with reference numerals “12a”, and the wiring layers 12 in a rough pattern region 14b are indicated with reference numerals “12b”. Metal that composes the conduction layer has been described above, and its description is not repeated.

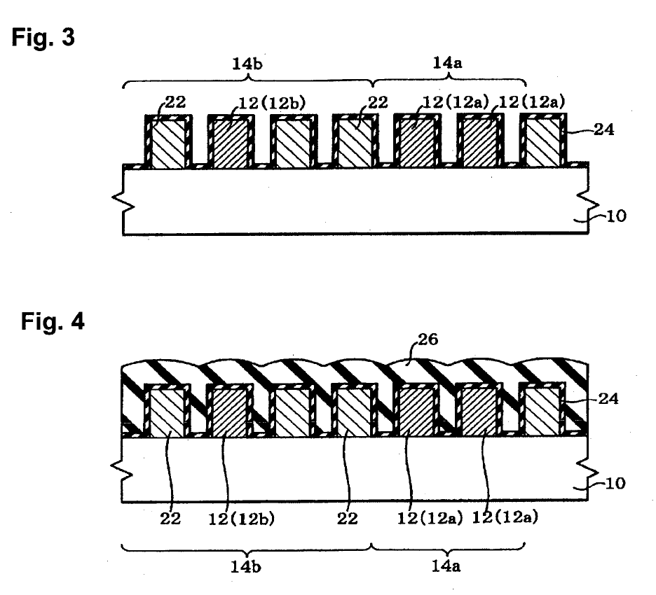

Next, as shown in FIG. 3, a base dielectric layer 24 is formed over the entire surface of the base 10 on which the wiring layers 12 (12a, 12b) and the stress relieving layers 22 are formed.

Then, as shown in FIG. 4, a planarization dielectric layer 26 in the form of a liquid dielectric member is formed on the base dielectric layer 24. The planarization dielectric layer 26 is formed in a manner to cover at least the base dielectric layer 24, and fill gaps between the wiring layers 12, between the wiring layers 12 and the stress relieving layers 22 and between the stress relieving layers 22 with the dielectric layers.

Then, as shown in FIG. 5, a cap dielectric layer 28 is formed over the entire surface of the planarization dielectric layer 26. The cap dielectric layer 28 has a thickness that sufficiently fills the surface roughness of the planarization dielectric layer 26, plus a thickness that is polished by a CMP process as necessary. The example shown in FIG. 5 indicates a state in which the top surface of the cap dielectric layer 28 has been planarized by a CMP process.

The interlayer dielectric layer 20 is composed of the base dielectric layer 24, the planarization dielectric layer 26 and the cap layer 28, which are formed in the above-described steps (b), (c) and (d).

One embodiment of the present invention has been described. However, the present invention is not limited to this embodiment, and many modifications can be made within the scope of the subject matter of the present invention. For example, the present invention can also be used in cases where a dielectric layer with a low dielectric constant formed by a coating method or a liquid CVD method is used as an interlayer dielectric layer.

The entire disclosure of Japanese Patent Application No. 2001-252729 filed Aug. 23, 2001 is incorporated by reference.

What is claimed is:

1. A semiconductor device comprising:
a wiring layer disposed in a specified pattern on a base;
a stress relieving layer disposed in a specified pattern on the base and formed from the same material as that of the wiring layer; and
an interlayer dielectric layer including at least a planarization dielectric layer that covers the wiring layer and the stress relieving layer and is formed from a liquid dielectric material.

2. A semiconductor device according to claim 1, wherein the planarization dielectric layer further comprises at least one of a silicon oxide layer formed by a coating method and another dielectric layer having a low dielectric constant formed by a coating method.

3. A semiconductor device according to claim 1, wherein the planarization dielectric layer further comprises at least one of a silicon oxide layer formed by a coating method and another dielectric layer having a low dielectric constant formed by a liquid CVD method.

4. A semiconductor device according to claim 1, wherein the stress relieving layer is disposed at least in a rough pattern region.

5. A semiconductor device according to claim 1, wherein the stress relieving layer has a minimum line width and a minimum gap for a wiring layer in an applied design rule.

6. A semiconductor device according to claim 1, wherein the interlayer dielectric layer further comprises a base dielectric layer formed on the wiring layer and the stress relieving layer, and a cap dielectric layer formed on the planarization dielectric layer.

7. A method for manufacturing a semiconductor device, the method comprising the steps of:
forming the wiring layer and a stress relieving layer having a specified pattern on the base; and
forming a planarization dielectric layer with a liquid dielectric material to cover the wiring layer and the stress relieving layer.

8. A method for manufacturing a semiconductor device according to claim 7, wherein the step of forming a planarization dielectric layer is performed by a coating method.

9. A method for manufacturing a semiconductor device according to claim 7, wherein the step of forming a planarization dielectric layer is performed by a liquid CVD method.

10. A method for manufacturing a semiconductor device according to claim 7, further comprising the steps of forming a base dielectric layer on the wiring layer and the stress relieving layer, and forming a cap dielectric layer on the planarization dielectric layer.

11. A semiconductor device comprising:
a base;
a first wiring layer disposed on the base;
a second wiring layer disposed on the base at a location spaced apart from the first wiring layer;
a stress relieving layer disposed between the first wiring layer and the second wiring layer, said stress relieving layer being selectively disposed adjacent and spaced apart from the first and second wiring layers; and
a dielectric layer covering the first wiring layer, the second wiring layer, the stress relieving layer and the base therebetween;
wherein the stress relieving layer is adapted to absorb compressive forces of the dielectric layer.

12. The semiconductor device of claim 11 wherein said stress relieving layer continuously extends along a major axis of said first wiring layer.

13. The semiconductor device of claim 11 wherein said stress relieving layer extends about a perimeter of said first wiring layer.

14. The semiconductor device of claim 13 wherein another stress relieving layer extends about a perimeter of said second wiring layer.

15. The semiconductor device of claim 14 wherein said second wiring layer further comprises a plurality of sub-wiring layers.

16. The semiconductor device of claim 11 further comprising a plurality of dummy wiring layers disposed adjacent said stress relieving layer.

17. The semiconductor device of claim 11 wherein said stress relieving layer is disposed at a minimum gap distance away from said first wiring layer, said minimum gap distance being derived from a given design rule.

18. The semiconductor device of claim 11 wherein said stress relieving layer includes a minimum width, said minimum width being derived from a given design rule.

19. A method of making a semiconductor device comprising:
forming a first wiring layer on a base;
forming a second wiring layer on the base spaced apart from the first wiring layer;
forming a stress relieving layer between the first and second wiring layers;
disposing a dielectric layer over the first wiring layer, the second wiring layer, the stress relieving layer, and the base therebetween; and
using the stress relieving layer to absorb a compressive force of the dielectric layer.

20. The method of claim 19 further comprising disposing at least one dummy wiring layer on said base.
